(19) United States
(12) Patent Application Publication
(10) Pub. No.: US 2026/0122909 A1
(43) Pub. Date: Apr. 30, 2026

(54) FERROELECTRIC MEMORY DEVICE AND OPERATING METHOD THEREOF

(71) Applicant: Samsung Electronics Co., Ltd., Suwon-si (KR)

(72) Inventors: Haewook JEONG, Suwon-si (KR); Changyoung LEE, Suwon-si (KR); Keonhee PARK, Suwon-si (KR); Young Seok PARK, Suwon-si (KR)

(73) Assignee: Samsung Electronics Co., Ltd., Suwon-si (KR)

(21) Appl. No.: 19/075,958

(22) Filed: Mar. 11, 2025

(30) Foreign Application Priority Data
Oct. 24, 2024 (KR) 10-2024-0146311

(51) Int. Cl. H10B 53/20; G11C 11/22; H01L 23/00; H01L 25/065; H01L 25/18; H10B 53/30; H10B 80/00

(52) U.S. Cl. CPC H10B 53/20; G11C 11/221; G11C 11/2259; G11C 11/2273; G11C 11/2275; H10B 53/30; H10B 80/00; H10W 90/00; H10W 90/792

(57) ABSTRACT

Disclosed is a ferroelectric memory device, comprising, a first plate line, a first ferroelectric capacitor connected to the first plate line, a first access transistor having a gate connected to a first word line, one end of which is connected to the first ferroelectric capacitor, and the other end of which is connected to a bit line, a global plate line, and a first plate line selection transistor configured to connect the global plate line and the first plate line in response to a first word line signal supplied to the first word line.

### CROSS-REFERENCE TO RELATED APPLICATIONS

This application claims priority under 35 U.S.C. § 119 to Korean Patent Application No. 10-2024-0146311 filed on Oct. 24, 2024, in the Korean Intellectual Property Office, the disclosures of which are incorporated by reference herein in their entireties.

### BACKGROUND

Embodiments of the present disclosure described herein relates to a semiconductor device, and more specifically, to a ferroelectric memory device configured to reducing the number of contact plugs and/or pads provided on a plate line, and an operating method thereof.

Ferroelectric random access memory (FRAM) devices are being studied as one of the non-volatile memory devices that are configured to maintain data even when power is removed. FRAM has a simpler structure than dynamic random access memory (DRAM), but may be implemented as a non-volatile memory device with high density like a flash memory device. Recently, FRAMs with three-dimensionally stacked structures are being developed to implement high density.

In order to overcome the scaling limit in a three-dimensional memory structure, a ‘1TnC’ structure FRAM is being studied. ‘1TnC’ refers to a form in which one access transistor ‘1T’ and ‘n’ ferroelectric capacitors ‘nC’ form one memory cell unit. However, in order to implement a ‘1TnC’ structure FRAM cell array in a three-dimensional structure, an excessively large number of plate line pads or contact plugs are required compared to the cell area. Therefore, a technology that reduces the number of plate line pads is being explored in the implementation of 3D FRAM devices.

### SUMMARY

Embodiments of the present disclosure provides a three-dimensional ferroelectric memory device with a reduced number of plate line pads and a method of driving the same.

According to at least one embodiment of the inventive concepts, a ferroelectric memory device comprises a first plate line; a first ferroelectric capacitor connected to the first plate line; a first access transistor, the first access transistor including a gate connected to a first word line, a first end connected to the first ferroelectric capacitor, and a second end connected to a bit line; a global plate line; and a first plate line selection transistor configured to connect the global plate line and the first plate line in response to a first word line signal supplied to the first word line.

According to at least one embodiment of the inventive concepts, a method of operating a ferroelectric memory device including memory cells each including a plurality of plate lines vertically stacked on a substrate, an access transistor, and a plurality of ferroelectric capacitors, includes: turning on the access transistors of each of the memory cells of a selected row such that the memory cells are connected to a bit line; applying a word line signal to the memory cells such that a plurality of global plate lines are connected to the plurality of plate lines, and applying a voltage to a selected global plate line corresponding to a selected ferroelectric capacitor among the plurality of ferroelectric capacitors, wherein each of the plurality of global plate lines and each of the plurality of plate lines are connected to respective plate line selection transistors that are configured to be driven in response to the word line signal.

According to at least one embodiment of the inventive concepts, a ferroelectric memory device includes a plurality of global plate lines connected to a plurality of plate lines vertically stacked on a substrate; a cell array including a plurality of memory cells, each of the plurality of memory cells at an intersection of a word line, of a plurality of word lines, and a bit line, of a plurality of bit lines; and an address decoder configured to transmit a word line signal to the word lines and a global plate line signal to the plurality of global plate lines, wherein each of the plurality of memory cells comprises a plurality of ferroelectric capacitors each connected to a corresponding plate line of the plurality of plate lines, and an access transistor configured to connect the plurality of bit lines to each of the plurality of ferroelectric capacitors in response to the word line signal, each of the plurality of plate lines in a layer unit are connected to a shared one of the plurality of global plate lines and to a plate line selection transistor configured to be operate based on the word line signal, and wherein the ferroelectric memory device is configured such that the word line signal and the global plate line signal collectively select one of the plurality of ferroelectric capacitors.

### BRIEF DESCRIPTION OF THE FIGURES

The above and other objects and features of the present disclosure will become apparent by describing in detail embodiments thereof with reference to the accompanying drawings.

FIG. 1 is a drawing showing a manufacturing process of a ferroelectric memory device according to at least one embodiment of the present inventive concepts.

FIG. 2 is a cross-sectional view showing a ferroelectric memory device according to at least one embodiment of the present inventive concepts.

FIG. 3 is a block diagram showing a ferroelectric memory device according to at least one embodiment of the present inventive concepts.

FIG. 4 is a cross-sectional view and an equivalent circuit diagram showing a memory cell MC of the 1TnC structure of FIG. 3.

FIG. 5 is a circuit diagram showing a structure of a three-dimensional array in which memory cells of the 1TnC structure are formed in a global plate line structure.

FIG. 6 is a circuit diagram briefly showing an example of applying a global plate line GPL to one memory cell MC.

FIG. 7 is a drawing showing the characteristics of a ferroelectric capacitor of the present inventive concepts.

FIG. 8 is a drawing explaining a write operation of a ferroelectric memory cell according to at least one embodiment of the present inventive concepts.

FIG. 9 is a drawing explaining a read operation of a ferroelectric capacitor of the present inventive concepts.

FIG. 10 is a graph showing a sensing method through a bit line voltage according to the discharge to a bit line of a ferroelectric capacitor during a read operation.

FIG. 11 is a waveform diagram showing a read and re-write operation in a global plate line structure according to at least one embodiment of the present inventive concepts.

FIG. 12 is a drawing showing a layout structure of a plate line contact plug according to a first embodiment.

FIG. 13 is a drawing showing a layout structure of a plate line contact plug according to a second embodiment.

FIG. 14 is a drawing showing a layout structure of a plate line contact plug according to a third embodiment.

FIG. 15 is a drawing showing a layout structure of a plate line contact plug according to a fourth embodiment.

### DETAILED DESCRIPTION

It is to be understood that both the foregoing general description and the following detailed description are examples, and it is to be considered that an additional description of the claimed invention is provided. Reference signs are indicated in detail in example embodiments of the present inventive concepts, examples of which are indicated in the reference drawings. Wherever possible, the same reference numbers are used in the description and drawings to refer to the same or like parts; in such cases a repeated description related thereto may be omitted for brevity.

In the drawings, sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

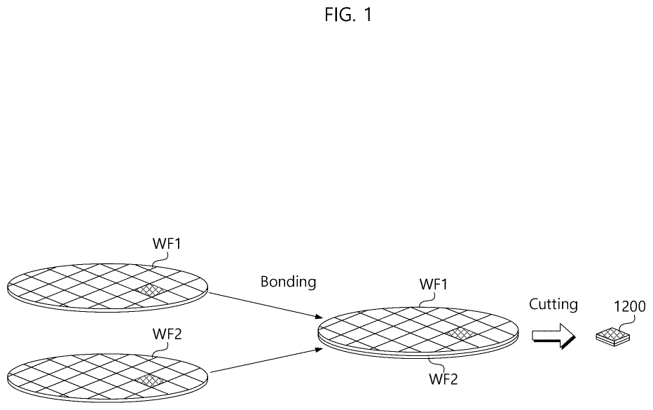

FIG. 1 is a drawing showing a manufacturing process of a ferroelectric memory device according to at least one embodiment of the present inventive concepts. Referring to FIG. 1, a ferroelectric memory device 1200 may be formed as a stacked semiconductor memory by applying a wafer bonding method.

Integrated circuits are formed on each of the first wafer WF1 and the second wafer WF2. For example, a cell array may be formed on the first wafer WF1, and a peripheral circuit (configured to control the cell array) may be formed on the second wafer WF2. The peripheral circuit may include a voltage generator, a decoder, a control circuit, etc.

The first wafer WF1 and the second wafer WF2 are bonded using a hybrid bonding method. That is, the metals (e.g., copper) of each of the first wafer WF1 and the second wafer WF2 are bonded to each other, and the dielectrics (e.g., oxide films) of each of the first wafer WF1 and the second wafer WF2 are bonded to each other. The surfaces of the first wafer WF1 and the second wafer WF2 are processed through a flattening and cleaning process for bonding. Then, the dielectrics are bonded by being pressurized under low pressure conditions. Finally, the metals filled in the upper and lower via holes are bonded through heat treatment.

The bonded wafers WF1 and WF2 are cut into a plurality of chips. Then, each of the cut chips is provided as a stacked ferroelectric memory device 1200 in which upper and lower semiconductor dies are bonded.

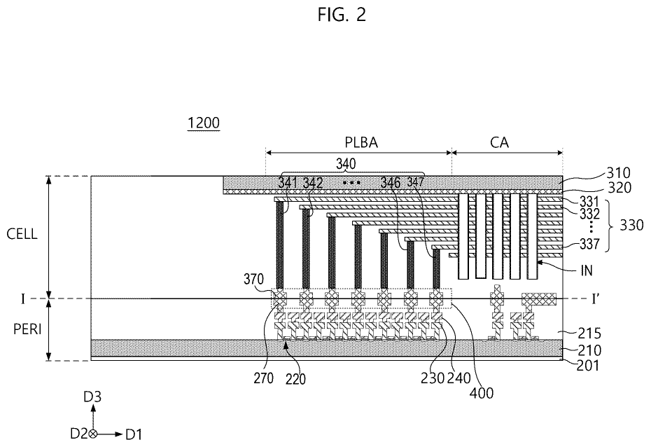

FIG. 2 is a cross-sectional view showing a ferroelectric memory device according to at least one embodiment of the present inventive concepts. Referring to FIG. 2, the ferroelectric memory device 1200 has a chip-to-chip (C2C) structure. In order to form a ferroelectric memory device 1200 with the C2C structure, an upper chip including a cell part CELL is manufactured on a first wafer, and a lower chip including a peripheral circuit part PERI is manufactured on a second wafer different from the first wafer. Thereafter, a ferroelectric memory device 1200 with the C2C structure is formed by bonding the upper chip and the lower chip at a bonding surface (I-I′).

The peripheral circuit part PERI may include a first substrate 210, an interlayer insulating layer 215, a plurality of circuit elements 220 formed on the first substrate 210, a first metal layer 230 connected to each of the plurality of circuit elements 220, and a second metal layer 240 formed on the first metal layer 230. In at least one embodiment, the first metal layer 230 may be formed of a first metal (e.g., tungsten) having relatively high resistance, and the second metal layer 240 may be formed of a second metal (e.g., copper) having relatively low resistance. However, the types of materials of the first metal layer 230 and the second metal layer 240 are not limited to the disclosure herein.

The interlayer insulating layer 215 is disposed on the first substrate 210 to cover the plurality of circuit elements 220, the first metal layer 230, and the second metal layer 240, and may include an insulating material such as silicon oxide, silicon nitride, a combination thereof, and/or the like. A lower bonding metal 270 may be formed on the second metal layer 240 of the plate line bonding area PLBA. In the plate line bonding area PLBA, the lower bonding metal 270 of the peripheral circuit part PERI may be electrically connected to the upper bonding metal 370 of the cell part CELL by a bonding method, and the lower bonding metal 270 and the upper bonding metal 370 may include aluminum, copper, tungsten, a combination thereof, and/or the like.

The cell part CELL may include a second substrate 310 and a base layer 320 on which an access transistor is formed. On the second substrate 310, a plurality of plate lines 330 (e.g., 331, 332, 333, 334, 335, 336, 337) may be laminated along a third direction D3 perpendicular to the upper surface of the second substrate 310.

In the plate line bonding area PLBA, the inner node IN may extend in a direction perpendicular to the upper surface of the second substrate 310 and penetrate the plate lines 330. The inner node IN may include a ferroelectric material layer, a channel layer, etc. In the plate line bonding area PLBA, the plate lines 330 may extend along a first direction D1 parallel to the upper surface of the second substrate 310 and may be connected to a plurality of contact plugs 340 (e.g., 341, 342, 343, 344, 345, 346, 347). The plate lines 330 and the contact plugs 340 may be connected to each other at pads provided by extending at least some of the plate lines 330 with different lengths along the first direction D1. The contact plugs 340 connected to the plate lines 330 may be connected to the peripheral circuit part PERI through the upper bonding metal 370 of the cell part CELL and the lower bonding metal 270 of the peripheral circuit part PERI in the plate line bonding area PLBA. Although not shown, one or more metal layers may be formed between the lower bonding metal 270 and upper bonding metal 370 of the contact plugs 340.

The contact plugs 340 transmit the plate line voltage VPL to each of the plate lines 330. The contact plugs 340 may also be referred to as plate line pads may be configured to provide an electrical connection with the outside of the chip. For example, the plate line voltage VPL is transmitted to the contact plugs 340 and the plate lines 330 via the lower bonding metal 270 and the upper bonding metal 370 connected to the upper portions of the first metal layer 230 and the second metal layer 240. Here, the bonds in which the lower bonding metal 270 and the upper bonding metal 370 are combined are referred to as plate line bonding 400. The plate line bonding 400 for providing the plate line voltage VPL to each of the plate lines 330 is formed by the lower bonding metal 270 and the upper bonding metal 370.

The contact plugs 340 or pads for connecting the upper bonding metal 370 and the plate lines 330 occupy a relatively large areas and resources. And, in order to form the three-dimensional FRAM of the ‘1TnC’ structure, there occurs a problem that the number of contact plugs 340 actually increases excessively. In the examples, a global plate line method and a word line structure are provided that may be used to reduce the number of contact pads or contact plugs 340 in the three-dimensional FRAM of the ‘1TnC’ structure.

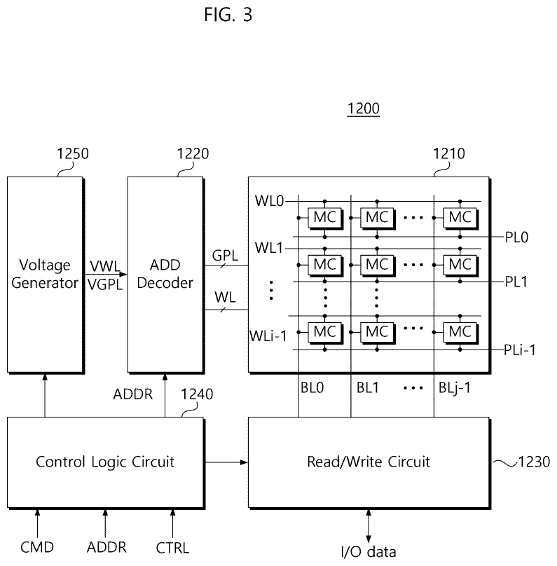

FIG. 3 is a block diagram showing a ferroelectric memory device according to at least one embodiment of the present inventive concepts. Referring to FIG. 3, a ferroelectric memory device 1200 may include a cell array 1210, an address decoder 1220, a read/write circuit 1230, a control logic circuit 1240, and a voltage generator 1250.

The cell array 1210 may include a plurality of ferroelectric memory cells MCs. In these cases, the ferroelectric memory device 1200 may be referred to as FeRAM (Ferroelectric Random Access Memory) or FRAM. The plurality of ferroelectric memory cells MCs may be respectively arranged in areas where word lines WL0 to WLi−1 and bit lines BL0 to BLj−1 intersect, and may form a matrix form. Each of the ferroelectric memory cells MCs may be connected to a corresponding word line WL and a bit line BL. Meanwhile, each of the ferroelectric memory cells MCs may be connected to at least one plate line PL. At this time, at least one plate line PL may be arranged corresponding to each word line WL, but is not limited thereto.

Each of the ferroelectric memory cells MCs may include an access transistor and at least one ferroelectric capacitor. At least one ferroelectric capacitor included in the ferroelectric memory cell MC may store and discharge a charge amount corresponding to data. According to at least one embodiment, a plurality of ferroelectric memory cells MCs may store multi-bit data. At this time, depending on the embodiment, one multi-bit data may be stored in one ferroelectric memory cell, or one multi-bit data may be stored in several ferroelectric memory cells. The ferroelectric memory cell(s) storing multi-bit data may be configured to store a charge amount corresponding to the multi-bit data by using ferroelectric capacitors included in the ferroelectric memory cell. And the charge amount stored in the ferroelectric capacitors may be discharged through a bit line connected to the ferroelectric memory cell.

In particular, the plate lines for configuring the cell array 1210 may be formed as a global plate line structure. Access to one memory cell MC is performed by turning on an access transistor AT by a word line and activating the plate line. Therefore, in the global plate line structure of the present inventive concepts, the access transistor AT and the plate line selection transistor PLST of all memory cells connected to the word line may be turned on by the word line signal VWL. The plate line selection transistor PLST may transmit the global plate line signal VGPL to each plate line of the memory cell MC according to the word line signal VWL. Finally, in the cell array 1210 of the global plate line structure, activation of one plate line may be achieved by a combination of a global plate line signal VGPL and a word line signal VWL. This structure will be described in more detail through the drawings described below.

The address decoder 1220 is configured to select either a word line of the cell array 1210 or a global plate line GPL in response to an address ADDR. The address decoder 1220 transmits a word line signal VWL to a word line of a selected memory area or memory cell. During a read or write operation, the address decoder 1220 may provide a word line signal VWL and a global plate line signal VGPL to select a memory cell or a plate line. The access transistor AT of the memory cell MC selected by the word line signal VWL is turned on. In addition, the plate line selection transistors PLSTs of each of the memory cells connected to the corresponding word line are turned on by the word line signal VWL. Then, the address decoder 1220 may activate the plate line of one of the memory cells by providing the global plate line signal VGPL to one selected one of the plurality of global plate lines.

The read/write circuit 1230 operates as a write driver or a sense amplifier for accessing the cell array 1210. The read/write circuit 1230 is configured to detect data stored in the memory cell MC. In particular, the read/write circuit 1230 may detect data stored in the memory cell MC by comparing the bit line voltage VBL according to the amount of charge released from the memory cell MC to the bit line BL with the reference voltage Vref. The data detected by the read/write circuit 1230 may be output to the outside of the ferroelectric memory device 1200. In addition, the read/write circuit 1230 may transmit write data input from the outside to the cell array 1210.

The control logic circuit 1240 is configured to control the read/write circuit 1230, the address decoder 1220, and the voltage generator 1250 in response to a command CMD transmitted from the outside. The control logic circuit 1240 may control the voltage generator 1250, the read/write circuit 1230, and the address decoder 1220 to perform write, read, and re-write operations on a selected memory cell according to the command CMD. To this end, the control logic circuit 1240 may include a command decoder (not shown) that is configured to decode the command CMD received from an external device (e.g., a host device). In at least some embodiments, the external device may include and/or use processing circuitry such as hardware, software, and/or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. In these cases, the external device may provide signals controlling (e.g., enabling, initiating, instructing, etc.) the functions and/or operations of the ferroelectric memory device 1200.

The voltage generator 1250 is configured to generate a word line signal VWL to be supplied to the word line WL and a global plate line signal VGPL to be supplied to the global plate line GPL under the control of the control logic circuit 1240. The voltage generator 1250 may also generate a bit line voltage VBL to be supplied to the bit line BL under the control of the control logic circuit 1240.

As described above, the ferroelectric memory device 1200 may include a cell array 1210 formed with a global plate line structure. Activation of any one plate line of a memory cell selected through the global plate line structure may be performed by a combination of the global plate line signal VGPL and the word line signal VWL. Through this structure, the area occupied by contact plugs or pads for electrically connecting the plate lines to the peripheral circuit part (PERI, see FIG. 2) may be minimized.

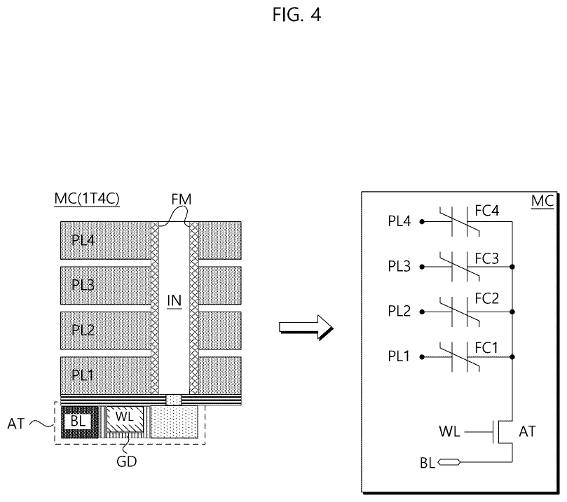

FIG. 4 is a cross-sectional view and an equivalent circuit diagram showing a memory cell MC of the 1TnC structure of FIG. 3. Referring to FIG. 4, a pillar or inner node IN is formed that penetrates plate lines PL1, PL2, PL3 and PL4 to form a memory cell MC. And a bit line BL and a word line WL for forming an access transistor AT are formed at the bottom. Here, the structure of a memory cell MC of the ‘1T4C’ structure in which one access transistor AT and four ferroelectric capacitors FC1 to FC4 are formed will be described as an example.

The inner node IN penetrates plate lines PL1, PL2, PL3 and PL4 and the insulating material therebetween (not illustrated) and is connected to the drain of the access transistor AT. As a result, the inner node IN may be considered to form the drain of the access transistor AT. A ferroelectric material FM is formed on the outer surface of the cylindrical inner node IN. The ferroelectric material FM may store data by polarization. The polarization state may be switched by an electric field formed between the inner node IN and the plate lines PL1, PL2, PL3 and PL4. The access transistor AT connects the bit line BL to the inner node IN according to the word line signal VWL transmitted to the word line WL. A gate electrode GD may be formed around the word line WL to form the access transistor AT.

A memory cell MC of the ‘1T4C’ structure is formed as shown in the equivalent circuit by the structure described above. And in order to activate one ferroelectric capacitor FCk, the access transistor AT must be turned on by the word line WL, and a plate line signal must be applied to one of the plate lines PL1, PL2, PL3 and PL4. In the case of the illustrated memory cell MC, the channel of the access transistor AT is formed as a two-dimensional transistor parallel to the substrate. However, the channel of the access transistor AT may be implemented as a transistor perpendicular to the substrate (e.g., vertical channel transistor). In these cases, the bit line BL may be located below the word line WL.

Meanwhile, each of the ferroelectric capacitors FCk may include a ferroelectric material. The ferroelectric material may be a material having a ferroelectric phase structure (e.g., at least one of a fluorite structure, a perovskite structure, and/or a wurtzite structure). In at least some embodiments, the ferroelectric phase may be a dominant phase of the ferroelectric material such that the ferroelectric material has ferroelectric property (e.g., compared to a comparative layer including a similar composition but different structure which would not exhibit the ferroelectric properties). The ferroelectric material may include at least one of lead zirconate titanate (PZT), strontium bismuth tantalate (SBT), and/or bismuth lanthanum titanate (BLT). In addition, the ferroelectric capacitor FCk may include, for example, at least one of hafnium oxide, hafnium zirconium oxide, zirconium oxide, barium strontium titanium oxide, barium titanium oxide, lead zirconium titanium oxide, a combination thereof, and/or the like. Here, the hafnium zirconium oxide may be a material in which zirconium (Zr) is doped into hafnium oxide, or may be a compound of hafnium (Hf), zirconium (Zr), and oxygen (O). Each of the ferroelectric capacitors FCk may further include a doping element doped into the above-described material. The doping element may be an element selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), tin (Sn), a combination thereof, and/or the like.

In the above, the memory cell MC structure of the ‘1T4C’ structure has been briefly described. However, the circuit structure of the illustrated memory cell MC structure is a simplified structure for convenience of explanation, and the actual memory block is not limited to the illustrated example. That is, it will be well understood that one memory cell MC may include more ferroelectric capacitors.

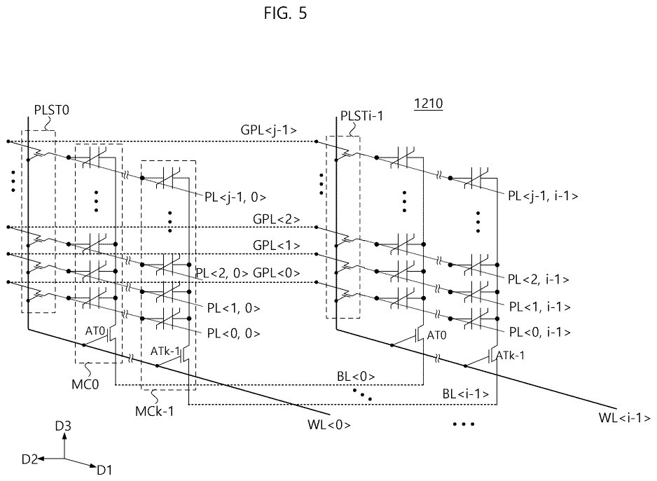

FIG. 5 is a circuit diagram showing the structure of a three-dimensional array in which memory cells of the ‘1TnC’ structure are formed in a global plate line structure. Referring to FIG. 5, the cell array 1210 shares the same global plate line GPL<k> with the ferroelectric capacitors of the same layer. And the access transistors ATs of the memory cells connected to the corresponding word line by one word line WL and the plate line selection transistors PLST for connecting the plate line of each layer and the global plate line are turned on simultaneously. Therefore, the contact plugs (340, see FIG. 2) or pads that must be formed for driving the plate lines may be formed only as many as the number of global plate lines GPL.

A plurality of memory cells MC0 to MCk−1 may be connected to the word line WL<0>. The access transistors AT0 to ATk−1 of each of the plurality of memory cells MC0 to MCk−1 may be turned on or off by the word line signal VWL supplied to the word line WL<0>. Each of the memory cells MC0˜MCk−1 may be connected to the corresponding bit line BL<0> to BL<i−1> only when the access transistors AT0˜ATk−1 are turned on.

The plate line selection transistors PLST0 are turned on or off according to the word line signal VWL supplied from the word line WL<0>. The plate line selection transistors PLST0 are configured to connect or disconnect (or block) the global plate lines GPL<0> to GPL<j−1> to the plate lines PL<0> to PL<j−1> of the same layer based on activation. For example, if the plate line selection transistors PLST0 are turned on by the word line signal VWL supplied to the word line WL<0>, the global plate lines GPL<0> to GPL<j−1> are connected to the plate lines PL<0, 0> to PL<j−1, 0> of the memory cells MC0 to MCk−1, respectively. Therefore, the activation of the ferroelectric capacitor of the selected memory cell depends on the global plate line signal VGPL applied to each of the global plate lines GPL<0> to GPL<j−1>. As such, contact plugs or pads do not need to be formed for all of the plate lines for the activation of the ferroelectric capacitor of each of the memory cells. Only the contact plugs or pads may be formed for each of the global plate lines GPL<0> to GPL<j−1>. That is, the contact plugs or pads may be formed only as many as the number of stacked plate lines. Therefore, the chip area for the contact plug or pad may be minimized.

Here, each of the word lines WL<0> to WL<i−1> must simultaneously control the access transistor AT of each of the memory cells and the plate line selection transistor PLST of each layer. Therefore, each of the word lines WL<0> to WL<i−1> extending in the horizontal direction D1 may be extended by changing the direction in the vertical direction D3. That is, each of the word lines WL<0> to WL<i−1> may be formed in the shape of the alphabet ‘L’. Each of the word lines WL<0> to WL<i−1> in the horizontal direction D1 may form common gate of access transistors AT0 to ATk−1, and each of the word lines WL<0> to WL<i−1> in the vertical direction D3 may form common gate of each of the plate line selection transistors PLST0 to PLSTi−1.

According to the cell array 1210 of the global plate line structure of the present inventive concepts illustrated, the plate lines of each layer may share the global plate line GPL of the same layer. In addition, each of the word lines WL<0> to WL<i−1> may turn on the plate line selection transistor PLST simultaneously with the access transistors AT of the connected memory cells. Therefore, a contact plug or pad for activating the plate line may be formed only on the global plate line GPL.

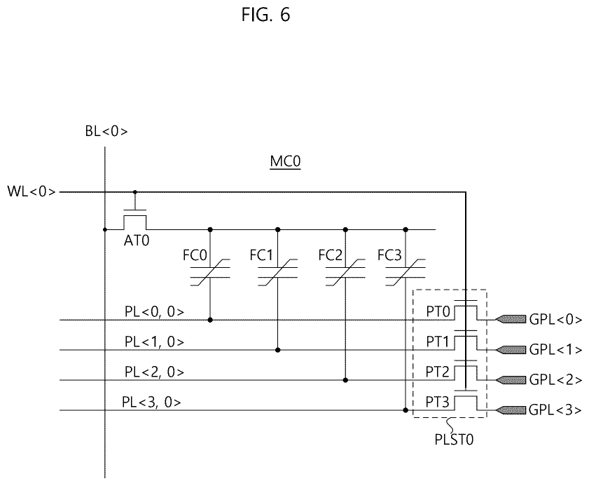

FIG. 6 is a circuit diagram briefly showing an example of applying a global plate line GPL to one memory cell MC. Referring to FIG. 6, a gate of an access transistor AT0 is connected to a word line WL<0>. And one end of an access transistor AT0 is connected to a bit line BL<0>. Ferroelectric capacitors FC0, FC1, FC2 and FC3 may be formed between the other end of the access transistor AT0 and each of the plate lines PL<0, 0>, PL<1, 0>, PL<2, 0> and PL<3, 0>.

Each of the plate lines PL<0, 0>, PL<1, 0>, PL<2, 0> and PL<3, 0> may be connected to each of the global plate lines GPL<0>, GPL<1>, GPL<2> and GPL<3> by plate line selection transistors PLST0. That is, the plate line PL<0, 0> formed in the first layer is connected to the global plate line GPL<0> by the plate line selection transistor PT0. The plate line PL<1, 0> formed in the second layer is connected to the global plate line GPL<1> by the plate line selection transistor PT1. The plate line PL<2, 0> formed in the third layer is connected to the global plate line GPL<2> by the plate line selection transistor PT2. The plate line PL<3, 0> formed in the fourth layer is connected to the global plate line GPL<3> by the plate line selection transistor PT3. Each of the global plate lines GPL<0>, GPL<1>, GPL<2> and GPL<3> is connected to all the plate lines of the corresponding layer.

In order to select the ferroelectric capacitor FC3 for reading or writing, a word line signal VWL will be applied to the word line WL<0> and a bit line voltage VBL will be applied to the bit line BL<0>. The access transistor AT0 is turned on by the word line signal VWL. The plate line selection transistors PT0, PT1, PT2 and PT3 are also turned on simultaneously with the access transistor AT0 by the word line signal VWL. In addition, a global plate line signal VGPL will be provided to the global plate line GPL<3> through a contact plug or pad to activate the plate line PL<3, 0>.

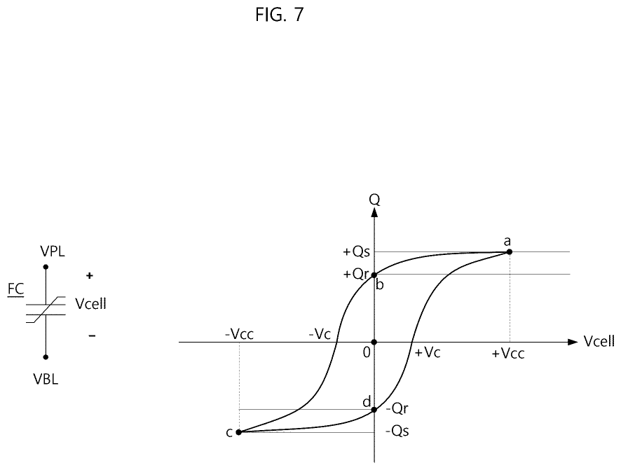

FIG. 7 is a drawing showing the hysteresis characteristic of the ferroelectric capacitor of the present inventive concepts. Referring to FIG. 7, the ferroelectric capacitor FC exhibits a hysteresis loop characteristic for the cell voltage Vcell applied to both ends.

The horizontal axis of the cell characteristic graph represents the cell voltage Vcell applied to both ends of the ferroelectric capacitor FC, and the vertical axis represents the total charge Q or polarization induced on the surface of the ferroelectric capacitor FC according to the cell voltage Vcell. In addition, ‘Qr’ represents the remnant charge, ‘Qs’ represents the saturation charge, and ‘Vc’ represents the coercive voltage, respectively. The coercive voltage Vc represents the voltage size that makes the total charge of the ferroelectric capacitor FC ‘0’. Meanwhile, ‘VPL’ and ‘VBL’ indicated on both ends of the ferroelectric capacitor FC represent the voltage applied through the plate line PL and the voltage applied through the bit line BL, respectively.

When the cell voltage Vcell increases from ‘0’ to the positive direction, polarization occurs in the ferroelectric material of the ferroelectric capacitor FC, and the total charge Q of the ferroelectric capacitor FC increases. When the cell voltage Vcell becomes a positive saturation voltage +Vcc, the total charge Q reaches the ‘a’ point corresponding to the saturation charge +Qs. At this time, even if the cell voltage Vcell increases further, the total charge Q does not increase any further. In other words, the ferroelectric capacitor FC enters a saturation polarization state when the cell voltage Vcell is greater than the positive saturation voltage +Vcc. After that, even if the cell voltage Vcell decreases to ‘0’ again, the polarization direction is maintained. Therefore, the total charge Q moves along the curve and reaches the ‘b’ point, which is a non-zero residual charge +Qr.

Meanwhile, when the cell voltage Vcell increases in the negative direction when the total charge Q is the residual charge (+Qr, point ‘b’), the total charge Q moves along the curve from point ‘b’, passes 0, and becomes the negative saturation charge (−Qs, point ‘c’). Even if the cell voltage Vcell increases in the negative direction more than the negative saturation voltage −Vcc, the total charge Q does not increase in the negative direction any further. That is, the ferroelectric capacitor FC enters a saturation polarization state even when the cell voltage Vcell is lower than the negative saturation voltage −Vcc. At this time, the polarization direction of the ferroelectric material of the ferroelectric capacitor FC becomes the opposite to that at point ‘a’. After that, even if the cell voltage Vcell becomes ‘0’ again, the polarization direction is maintained, and the total charge Q moves along the curve and becomes a negative residual charge (−Qr, ‘d’ point) that is not ‘0’. On the other hand, if the cell voltage Vcell is increased in the positive direction again at the ‘d’ point, the total charge moves along the curve from the ‘d’ point, passes 0, and changes to the ‘a’ point.

According to the above, when a cell voltage Vcell having a positive saturation voltage +Vcc or a negative saturation voltage −Vcc is applied to both ends of a ferroelectric capacitor FC, the polarization direction according to spontaneous polarization is maintained even if the applied voltage is removed. The surface charge of the ferroelectric material due to spontaneous polarization is not naturally lost due to leakage, etc. If a coercive voltage (+Vc or −Vc) is not applied so that the polarization degree becomes ‘0’, the polarization direction is maintained as is.

According to at least one embodiment, a state in which a positive saturation voltage +Vcc is applied to both terminals of a ferroelectric capacitor FC and then removed, (e.g., a state in which the total charge Q is a positive residual charge (+Qr, ‘b’ point)) may correspond to a state in which data ‘0’ is stored in the ferroelectric capacitor FC. In addition, a state in which a negative saturation voltage −Vcc is applied to both terminals of the ferroelectric capacitor FC and then removed (e.g., a state in which the total charge Q is a negative residual charge (−Qr, ‘d’ point)) may correspond to a state in which data ‘1’ is stored in the ferroelectric capacitor FC. However, the logical value of the data to be stored is not limited to the disclosure herein.

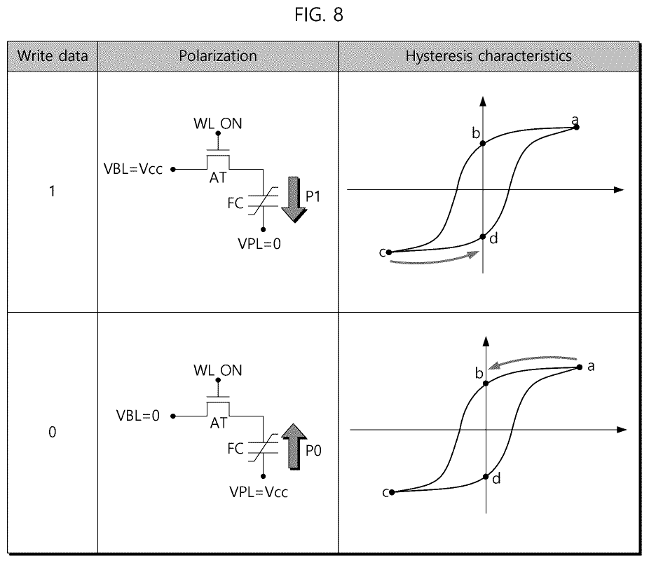

FIG. 8 is a drawing explaining a write operation of a ferroelectric memory cell according to at least one embodiment of the present inventive concepts. Referring to FIG. 8, saturation polarization in different directions occurs in the ferroelectric capacitor FC depending on the data being written.

In the write operation of data ‘1’, a word line signal VWL for turning on the access transistor AT is applied to the word line WL. Then, a saturation voltage Vcc is applied to the bit line BL and 0 V is applied to the plate line PL. Then, the cell voltage Vcell at both ends of the ferroelectric capacitor FC becomes a negative saturation voltage −Vcc. At this time, saturation polarization in the ‘P1’ direction occurs in the ferroelectric capacitor FC. And the total charge Q of the ferroelectric capacitor FC is located at the ‘c’ point. Afterwards, even if the cell voltage Vcell is removed, the polarization direction is maintained, and the total charge Q moves to the ‘d’ point. In this way, data ‘1’ may be written to the ferroelectric capacitor FC.

During the write operation of data ‘0’, the word line signal VWL is applied to the word line WL to turn on the access transistor AT. Then, 0 V is applied to the bit line BL and a positive saturation voltage +Vcc is applied to the plate line PL. Then, the cell voltage Vcell at both ends of the ferroelectric capacitor FC becomes a positive saturation voltage +Vcc. At this time, saturation polarization in the ‘P0’ direction occurs in the ferroelectric capacitor FC, and the total charge Q of the ferroelectric capacitor FC is located at the ‘a’ point. After that, even if the cell voltage Vcell is removed, the polarization direction is maintained, and the total charge moves to the ‘b’ point. As described above, writing of data ‘0’ to the ferroelectric capacitor FC is performed.

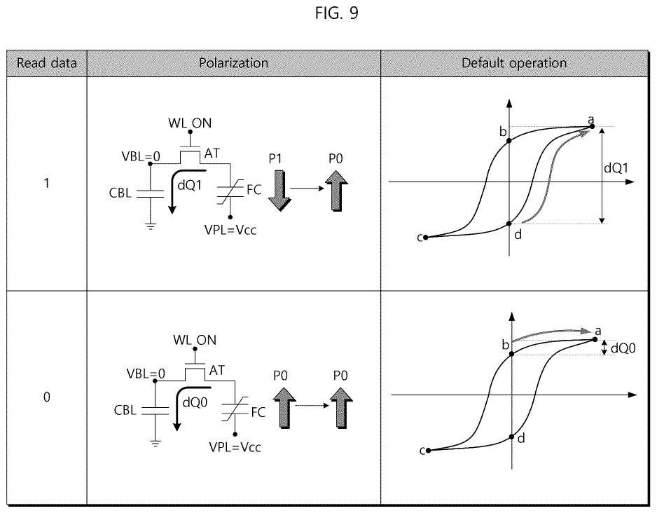

FIG. 9 is a drawing explaining a read operation of the ferroelectric capacitor of the present inventive concepts. Referring to FIG. 9, when reading data stored in the ferroelectric capacitor FC, a plate line voltage VPL at the saturation voltage Vcc level is provided to the plate line PL. Then, a word line signal VWL for turning on the access transistor AT is applied to the gate of the access transistor AT. In this state, the polarization direction of the ferroelectric capacitor FC may be switched or maintained depending on the stored data.

During the read operation, a voltage of the same level as the voltage for writing data ‘0’ may be applied to both ends of the ferroelectric capacitor FC. For example, during the read operation, the bit line BL may be pre-charged to 0 V, and a saturation voltage Vcc may be applied to the plate line PL. In this case, the polarization direction of the ferroelectric capacitor FC may be switched or maintained depending on the type of stored data. When the polarization direction is switched, a relatively large amount of charge is discharged from the ferroelectric capacitor FC to the bit line BL. On the other hand, when the polarization direction is maintained, a relatively small amount of charge is be discharged from the ferroelectric capacitor FC to the bit line BL. Based on the difference in the amount of charge discharged to the bit line BL, the sense amplifier (not shown) of the read/write circuit 1230 may identify the data.

When data ‘1’ is stored in the ferroelectric capacitor FC, the total charge Q of the ferroelectric capacitor FC is located at the ‘d’ point, and the polarization direction corresponds to ‘P1’. At this time, a word line signal VWL is applied to turn on the access transistor AT to the word line WL, and the bit line BL is pre-charged to zero volts (0 V). Then, when the saturation voltage Vcc is applied to the plate line PL, the polarization direction is switched to ‘P0’. Then, the total charge amount Q of the ferroelectric capacitor FC moves from the ‘d’ point to the ‘a’ point. In this case, the charge amount dQ1 corresponding to the difference between the ‘d’ point and the ‘a’ point may be released to the bit line BL through the access transistor AT.

In the state where data ‘0’ is stored, the total charge amount of the ferroelectric capacitor FC is located at the ‘b’ point, and the polarization direction corresponds to ‘P0’. At this time, a word line signal VWL for turning on the access transistor AT is applied to the word line WL, and the bit line BL is pre-charged to 0 V. Then, when the saturation voltage Vcc is applied to the plate line PL, the total charge Q of the ferroelectric capacitor FC moves from the ‘b’ point to the ‘a’ point. In this case, the polarization direction is maintained as it is, and the charge amount dQ0 corresponding to the difference between the ‘b’ point and the ‘a’ point may be released to the bit line BL through the access transistor AT.

Meanwhile, since the bit line BL has a capacitance component CBL, when the charge amount is released to the bit line BL, the bit line voltage VBL corresponding to the released charge amount may be applied to the bit line BL. At this time, the level of the bit line voltage VBL may be proportional to the level of the charge amount released to the bit line BL. Therefore, the sense amplifier (not shown) may determine the type of data stored in the ferroelectric capacitor FC by comparing the bit line voltage VBL and the reference voltage Vref.

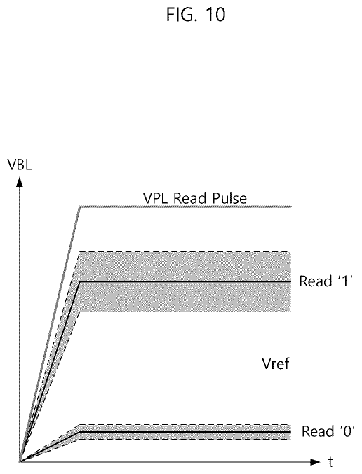

FIG. 10 is a graph showing a sensing method through a bit line voltage VBL according to the discharge of charge to a bit line of a ferroelectric capacitor FC during a read operation. Referring to FIG. 10, the amount of charge discharged to a bit line BL during the read operation varies depending on the data stored in the ferroelectric capacitor FC. The level of the bit line voltage VBL according to the amount of the discharged charge during the read operation is detected to identify the stored data.

When data ‘1’ is stored in the ferroelectric capacitor FC, a relatively large amount of charge, ‘dQ1’, will be discharged to the bit line BL. Therefore, a bit line voltage VBL higher than a reference voltage Vref may be set to the bit line BL. A sense amplifier (not shown) may detect a bit line voltage VBL higher than a reference voltage Vref and identify it as data ‘1’. On the other hand, if data ‘0’ is stored in the ferroelectric capacitor FC, a relatively small charge amount ‘dQ0’ will be released to the bit line BL. Therefore, a bit line voltage VBL lower than the reference voltage Vref may be set to the bit line BL. A sense amplifier (not shown) may detect the bit line voltage VBL lower than the reference voltage Vref and identify it as data ‘0’.

On the other hand, if data ‘1’ is detected, a bit line voltage VBL corresponding to data ‘1’ will be set on the bit line BL. Therefore, by lowering the voltage of the plate line PL to 0 V, data ‘1’ may be reprogrammed to the ferroelectric capacitor FC. This operation may be called a write back operation.

The above has explained the case where data is written or read to one ferroelectric capacitor FC. However, it will be well understood that data writing or reading operations may be performed for each of the plurality of ferroelectric capacitors in the above-described manner even in the ferroelectric memory cell of the ‘1TnC’ structure.

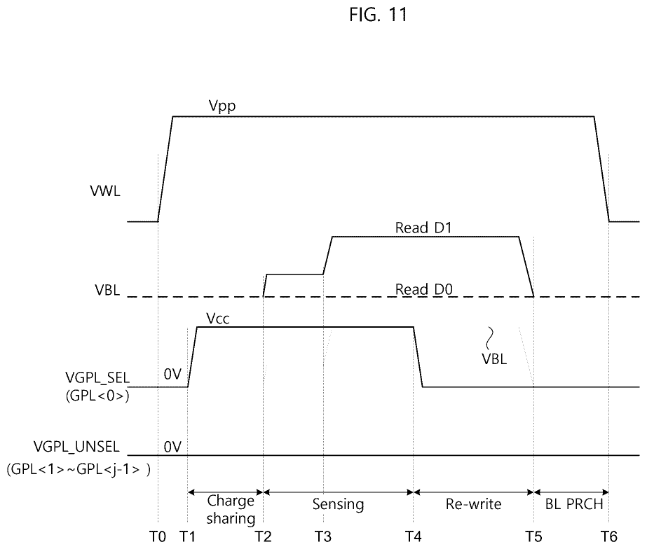

FIG. 11 is a waveform diagram briefly showing a read and re-write operation in a global plate line structure according to at least one embodiment of the present inventive concepts. Referring to FIG. 5 and FIG. 11, a case in which global plate line GPL<0> are selected among a plurality of global plate lines GPL<0> to GPL<j−1> and a word line WL<0> is selected will be described as an example.

At time T0, a word line signal VWL is applied to a word line WL<0> corresponding to a selected row. A relatively high voltage (for example, 3V) may be applied to the word line signal VWL. By supplying the word line signal VWL, the access transistors AT0 to ATk−1 whose gates are connected to the word line WL<0> are turned on. In addition, the plate line selection transistors PLSTs for each layer whose gates are connected to the word line WL<0> will be turned on.

At time T1, the global plate line signal VGPL is applied to the selected global plate line GPL<0>. The global plate line signal VGPL may be provided at, for example, a saturation voltage Vcc level. On the other hand, 0 V will be provided to the unselected global plate lines GPL<1> to GPL<j−1>. By supplying the global plate line signal VGPL to the selected global plate line GPL<0>, a positive saturation voltage +Vcc is applied to both ends of the ferroelectric capacitor FC connected to the global plate line GPL<0> of the memory cell MC<0>.

At time T2, the ferroelectric capacitor FC will discharge a charge (‘dQ1’ or ‘dQ0’) proportional to the difference between the saturation polarization value at the positive saturation voltage +Vcc state and the previous state polarization value. In other words, charge sharing occurs.

At time T3, the sense amplifier of the read/write circuit 1230 amplifies the size of the bit line voltage VBL set by the discharge charge amount (‘dQ1’ or ‘dQ0’). The sense amplifier determines the data stored in the ferroelectric capacitor FC as ‘1’ or ‘0’ according to the level of the amplified bit line voltage VBL.

At time T4, when the global plate line signal VGPL supplied to the selected global plate line GPL<0> is blocked, rewriting of the ferroelectric capacitor FC begins. The negative saturation voltage −Vcc is applied again to both ends of the ferroelectric capacitor FC where data ‘1’ is read, and as a result, data ‘1’ is written again to the ferroelectric capacitor FC. On the other hand, in the case of the ferroelectric capacitor FC where data ‘0’ is read, since no data destruction occurs, the voltage at both ends of the ferroelectric capacitor FC is maintained at 0 V.

At time T5, the bit line pre-charge period BL PRCH following the re-write period begins. Afterwards, at time T6, when the word line signal VWL is deactivated to a low level, the read and re-write operation sequence of the selected ferroelectric capacitor FC is terminated.

As described above, the selection of one ferroelectric capacitor FC of the memory cell may be selected through a combination of the word line WL and the global plate line signal VGPL. Therefore, the number of contact plugs or pads for each plate line may be dramatically reduced.

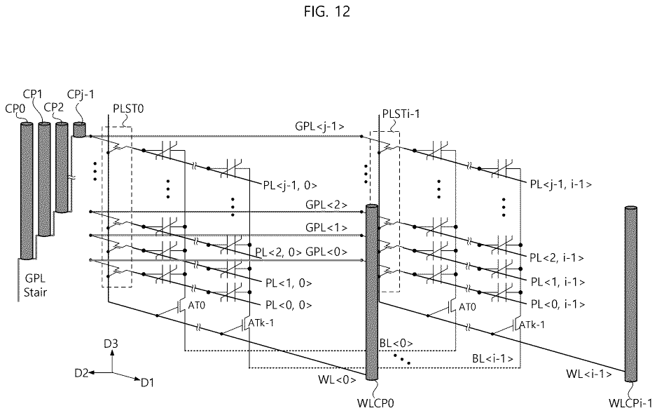

FIG. 12 is a drawing showing the arrangement structure of a plate line contact plug according to the first embodiment. Referring to FIG. 12, in the global plate line structure, pads or plate line contact plugs CP0 to CPj−1 for inter-chip bonding may be formed one by one for each of the global plate lines GPL<0> to GPL<j−1>. In addition, word line contact plugs WLCP0 to WLCPi−1 corresponding to each of the word lines WL<0> to WL<i−1> may be formed.

Plate lines (e.g., PL<1, 0> to PL<1, i−1>) located in the same layer are connected to one global plate line GPL<1> through plate line selection transistor (PLST0 to PLSTi−1). The access transistors AT0 to ATk−1 and the plate line selection transistor PLST0 corresponding to the row selected by the word line (e.g., WL<0>) are all activated. Therefore, in the cell array of the global plate line structure, the memory cell or the ferroelectric capacitor FC of the selected row may be selected through the combination of the word line signal VWL and the global plate line signal VGPL.

Therefore, the plate line voltage VPL application to the selected ferroelectric capacitor FC may be performed via the global plate lines GPL<0> to GPL<j−1>. That is, the plate line voltage VPL application to each ferroelectric capacitor FC of the cell array 1210 is performed in units of global plate lines GPL<0> to GPL<j−1> rather than individual plate lines (PL<0, 0> to PL<j−1, i−1>). Therefore, the contact plug or pad for transmitting the plate line voltage VPL may be formed in units of global plate lines GPL<0> to GPL<j−1>.

The global plate lines GPL<0> to GPL<j−1> may be formed in a staircase shape (e.g., GPL Stair) that does not overlap with different layers as illustrated. And by forming one plate line contact plug for each staircase, a C2C structure may be formed. In other words, one plate line contact plug CP0 may be formed in the global plate line GPL<0> shared by the plate lines PL<0, 0> to PL<0, i−1>. And one plate line contact plug CP1 may be formed in the global plate line GPL<1> connected to the plate lines PL<1, 0> to PL<1, i−1> so as not to overlap with the upper layer of the global plate line GPL<0>. One plate line contact plug CP2 may be formed on the global plate line GPL<2> connected to the plate lines PL<2, 0> to PL<2, i−1> so as not to overlap on the upper layer of the global plate line GPL<1>. In this way, plate line contact plugs CP0 to CPj−1 may be formed to correspond to the global plate lines GPL<0> to GPL<j−1>, respectively. In addition, one of the corresponding word line contact plugs WLCP0 to WLCPi−1 may be formed on the word lines WL<0> to WL<i−1>.

According to the configuration of the plate line contact plugs CP0 to CPj−1 in the above-described global plate line structure, the number of plate line contact plugs for driving the plate line may be drastically reduced.

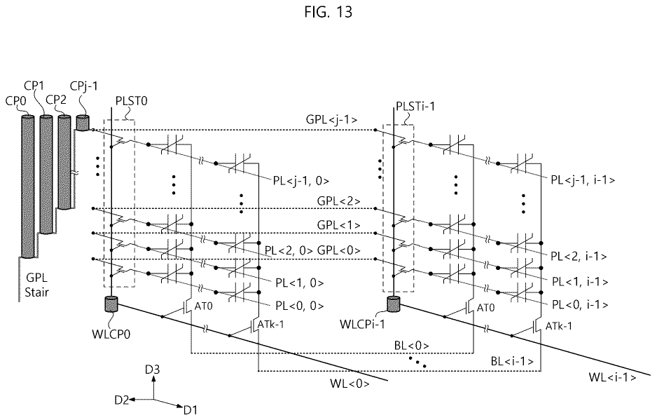

FIG. 13 is a drawing showing the arrangement structure of the plate line contact plug according to the second embodiment. Referring to FIG. 13, in the global plate line structure, pads or plate line contact plugs CP0 to CPj−1 for inter-chip bonding may be formed one by one for each of the global plate lines GPL<0> to GPL<j−1>. And word line contact plugs WLCP0 to WLCPi−1 corresponding to each of the word lines WL<0> to WL<i−1> may be formed.

Here, unlike FIG. 12, the word line contact plugs WLCP0 to WLCPi−1 may be formed on the same side in the D1 direction where the plate line contact plugs CP0 to CPj−1 are formed. That is, the word line contact plugs WLCP0 to WLCPi−1 may be formed to connect the word line and the pad in a lower layer than the layers where the plate line contact plugs CP0 to CPj−1 are formed. In particular, the word line contact plugs WLCP0 to WLCPi−1 may be extended from the upper side of the gate side of the plate line selection transistor PLST0 to PLSTi−1 to each of the word lines WL<0> to WL<i−1>.

According to the configuration of the plate line contact plugs CP0 to CPj−1 in the global plate line structure described above, the number of plate line contact plugs for driving the plate line may be drastically reduced.

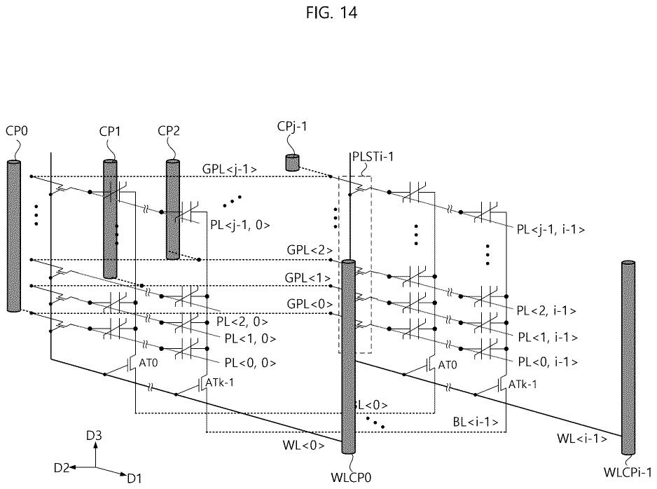

FIG. 14 is a drawing showing the arrangement structure of a plate line contact plug according to the third embodiment. Referring to FIG. 14, in the global plate line structure, pads or plate line contact plugs CP0 to CPj−1 for inter-chip bonding may be formed one by one for each of the global plate lines GPL<0> to GPL<j−1>. In addition, word line contact plugs WLCP0 to WLCPi−1 corresponding to each of the word lines WL<0> to WL<i−1> may be formed. In particular, the plate line contact plugs CP0 to CPj−1 are connected to the global plate lines GPL<0> to GPL<j−1> formed in a step shape in the D2 direction. Therefore, there is no need to occupy an excessive chip area in the D1 direction in order to form the plate line contact plugs CP0 to CPj−1.

The global plate lines GPL<0>˜GPL<j−1> may be formed in a stair shape (e.g., GPL Stair) that does not overlap with other layers in a diagonal direction in the ‘D2×D3’ plane as illustrated. And since one plate line contact plug is formed for each stair, pads or bonding for C2C may be formed on top of the plate line contact plugs CP0 to CPj−1. In addition, word line contact plugs WLCP0 to WLCPi−1 may be formed on the opposite side of the plate line contact plugs CP0 to CPj−1 centered on the cell array 1210 in the word lines WL<0> to WL<i−1>.

According to the configuration of the plate line contact plugs CP0˜CPj−1 in the global plate line structure described above, the number of plate line contact plugs for driving the plate line may be drastically reduced.

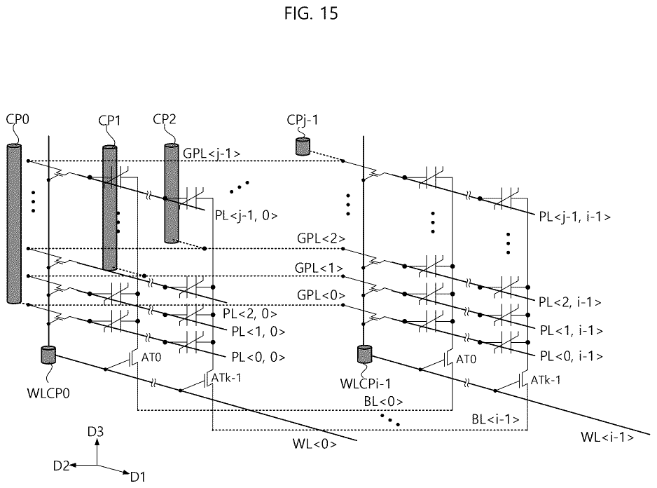

FIG. 15 is a drawing showing the arrangement structure of a plate line contact plug according to the fourth embodiment. Referring to FIG. 15, in the global plate line structure, pads or plate line contact plugs CP0 to CPj−1 for inter-chip bonding may be formed one by one for each of the global plate lines GPL<0> to GPL<j−1>. And word line contact plugs WLCP0 to WLCPi−1 corresponding to each of the word lines WL<0> to WL<i−1> may be formed. The plate line contact plugs CP0 to CPj−1 may be formed in substantially the same manner as those of FIG. 14 described above.

In particular, word line contact plugs WLCP0 to WLCPi−1 may be formed on the same side as the plate line contact plugs CP0 to CPj−1 with respect to the cell array 1210 as the center of the word lines WL<0> to WL<i−1>. That is, unlike FIG. 14, the word line contact plugs WLCP0 to WLCPi−1 may be formed on the same side as the plate line contact plugs CP0 to CPj−1 in the D1 direction. In other words, the word line contact plugs WLCP0 to WLCPi−1 may be formed to connect the word line and the pad in a lower layer than the layers in which the plate line contact plugs CP0 to CPj−1 are formed. In addition, the word line contact plugs WLCP0 to WLCPi−1 may be extended from the upper side of the gate side of the plate line selection transistor PLST0 to PLSTi−1 to each of the word lines WL<0> to WL<i−1>.

Depending on the method of forming the plate line contact plugs CP0 to CPj−1 in the global plate line structure described above, the number of plate line contact plugs for driving the plate line may be drastically reduced.

The above are specific embodiments for carrying out the present inventive concepts. In addition to the above-described embodiments, the present inventive concepts may include simple design changes or easily changeable embodiments. In addition, the present inventive concepts will include techniques that may be easily modified and implemented using the embodiments. Therefore, the scope of the present inventive concepts should not be limited to the above-described embodiments, and should be defined by the claims and equivalents of the claims of the present inventive concepts as well as the claims to be described later.

What is claimed is:

1. A ferroelectric memory device, comprising:
a first plate line;
a first ferroelectric capacitor connected to the first plate line;
a first access transistor, the first access transistor including a gate connected to a first word line, a first end connected to the first ferroelectric capacitor, and a second end connected to a bit line;
a global plate line; and
a first plate line selection transistor configured to connect the global plate line and the first plate line in response to a first word line signal supplied to the first word line.

2. The device of claim 1, wherein the first ferroelectric capacitor is configured to be selected through the first word line signal and a global plate line signal supplied to the global plate line.

3. The device of claim 1, wherein the first word line is connected to a gate of the first plate line selection transistor, and the first plate line selection transistor is configured to connect or disconnect the global plate line from the first plate line based on the first word line signal.

4. The device of claim 1, further comprising:
a second plate line;
a second ferroelectric capacitor connected to the second plate line;
a second access transistor, the second access transistor including a gate connected to a second word line, a first end connected to the second ferroelectric capacitor, and a second end connected to the bit line; and
a second plate line selection transistor configured to connect the global plate line and the second plate line in response to a second word line signal supplied to the second word line.

5. The device of claim 4, wherein the device is configured such that, during a read operation of data stored in the first ferroelectric capacitor, the first word line signal is activated and the second word line signal is deactivated.

6. The device of claim 5, wherein the device is configured such that, during the read operation, the global plate line is provided with a saturation voltage.

7. The device of claim 6, wherein the device is configured such that, during the read operation, the bit line is pre-charged to zero volts (0 V), and data is sensed according to an amount of charge shared from the first ferroelectric capacitor.

8. The device of claim 4, further comprising:
at least one a contact plug or a contact pad configured to electrically connect the global plate line to an external device.

9. A method of operating a ferroelectric memory device, the ferroelectric memory device including memory cells each including a plurality of plate lines vertically stacked on a substrate, an access transistor, and a plurality of ferroelectric capacitors, the method comprising:
turning on the access transistors of each of the memory cells of a selected row such that the memory cells are connected to a bit line;
applying a word line signal to the memory cells such that at least one of a plurality of global plate lines is connected to a corresponding plate line of the plurality of plate lines; and
applying a voltage to a selected global plate line corresponding to a selected ferroelectric capacitor among the plurality of ferroelectric capacitors,
wherein each of the plurality of global plate lines and each of the plurality of plate lines are connected to respective plate line selection transistors that are configured to be driven in response to the word line signal.

10. The method of claim 9, wherein, in a read operation for the selected ferroelectric capacitor,
the applied voltage includes a saturation voltage applied to the selected global plate line, and
a ground voltage is applied to unselected global plate lines.

11. The method of claim 10, further comprising:
identifying data according to an amount of charge discharged to the bit line,
wherein the amount of the charge discharged to the bit line is based on whether a polarization direction of the selected ferroelectric capacitor is switched during the read operation.

12. The method of claim 11, further comprising:
rewriting the selected ferroelectric capacitor by blocking the voltage supplied to the selected global plate line during the read operation.

13. The method of claim 9, wherein, in a write operation for the selected ferroelectric capacitor, the applying the voltage to the selected global plate line includes
providing a saturation voltage to the selected global plate line when data ‘0’ is written, and
providing a ground voltage to the selected global plate line when data ‘1’ is written.

14. The method of claim 9, further comprising:
applying a ground voltage to at least one unselected global plate line corresponding to unselected ferroelectric capacitors from among the plurality of ferroelectric capacitors.

15. The method of claim 14, wherein the plurality of global plate lines includes at least one of contact plugs or a contact pads, and
the applying the voltage to the selected global plate line and the applying the ground voltage to the at least one unselected global plate line respectively include transmitting a saturation voltage and the ground voltage through the at least one of the contact plugs or the contact pads.

16. A ferroelectric memory device comprising:
a plurality of global plate lines connected to a plurality of plate lines vertically stacked on a substrate;
a cell array including a plurality of memory cells, each of the plurality of memory cells at an intersection of a word line, of a plurality of word lines, and a bit line, of a plurality of bit lines; and
an address decoder configured to transmit a word line signal to the word lines and a global plate line signal to the plurality of global plate lines,
wherein each of the plurality of memory cells comprises
a plurality of ferroelectric capacitors each connected to a corresponding plate line of the plurality of plate lines, and
an access transistor configured to connect the plurality of bit lines to each of the plurality of ferroelectric capacitors in response to the word line signal,
wherein each of the plurality of plate lines in a layer unit are connected to a shared one of the plurality of global plate lines and to a plate line selection transistor configured to be operate based on the word line signal, and
wherein the ferroelectric memory device is configured such that the word line signal and the global plate line signal collectively select one of the plurality of ferroelectric capacitors.

17. The device of claim 16, wherein the ferroelectric memory device is configured such that one of the plurality of word lines and one of the plurality of plate lines is selected by the word line signal.

18. The device of claim 17, wherein the ferroelectric memory device is configured such that a saturation voltage or a ground voltage is provided to a ferroelectric capacitor connected to one of the selected plate lines based on the global plate line signal.

19. The device of claim 16, wherein the plurality of word lines includes a first word line corresponding to a first row, the first word line extending in a first direction parallel to the substrate and connected to gates of each of the access transistors of memory cells, of the plurality of memory cells, corresponding to the first row.

20. The device of claim 19, wherein the first word line includes in bend in a direction perpendicular to the substrate and each of the global plate lines is connected to gates of each of a plurality of plate line selection transistors corresponding to each layer unit and corresponding to the first row.
